(19) United States
(12) Patent Application Publication
(10) Pub. No.: US 2026/0223311 A1
(43) Pub. Date: Jul. 30, 2026

(54) CABLE ASSEMBLY, CABLE UNIT AND CABINET GROUP ASSEMBLY

(71) Applicant: Douyin Vision Co., Ltd., Beijing (CN)

(72) Inventors: Shiqiang LI, Beijing (CN); Jian WANG, Beijing (CN); Chenghua LIU, Beijing (CN)

(21) Appl. No.: 19/340,167

(22) Filed: Sep. 25, 2025

(30) Foreign Application Priority Data
Jan. 26, 2025 (CN) 202510125439.5

(51) Int. Cl. H05K 7/14

(52) U.S. Cl. CPC H05K 7/1491; H05K 7/1492

(57) ABSTRACT

A cable assembly, a cable unit and a cabinet group assembly are provided. The cable assembly includes two groups of connection terminals and at least two cables connected between the two groups of connection terminals. One of the two groups of connection terminals is configured to be connected to a first cabinet body, and the other of the two groups of connection terminals is configured to be connected to a second cabinet body. The cables connected between the two groups of connection terminals are configured to span across a front side of the first cabinet body and a front side of the second cabinet body.

The present disclosure claims priority to Chinese Patent Application No. 202510125439.5, filed on Jan. 26, 2025, which is incorporated herein by reference in its entirety as a part of the present disclosure.

### TECHNICAL FIELD

The present disclosure relates to the technical field of cable arrangement, and specifically, to a cable assembly, a cable unit, and a cabinet group assembly.

### BACKGROUND

With the rapid development of electronic devices and communication technologies, the arranging density of cables is increasing day by day, and the orderly arrangement of cables and later operation and maintenance have become crucial in various cabinets. In the related art, the cables are densely arranged, arranged in a mess, and have a long arrangement path, which causes great difficulties in installation or operation and maintenance, and is costly.

### SUMMARY

This section is provided for a concise introduction of the concepts, which will be described in detail in the following Detailed Description section. This section is neither intended to identify key or necessary features of the claimed technical solutions, nor is intended to be used to limit the scope of the claimed technical solutions.

In a first aspect, the present disclosure provides a cable assembly, including two groups of connection terminals and at least two cables connected between the two groups of connection terminals, where one of the two groups of connection terminals is configured to be connected to a first cabinet body, the other of the two groups of connection terminals is configured to be connected to a second cabinet body, and the cables connected between the two groups of connection terminals are configured to span across a front side of the first cabinet body and a front side of the second cabinet body.

In a second aspect, the present disclosure provides a cable unit, including a cable management rack and the cable assembly provided by the present disclosure, where the cable management rack is supported below the cable assembly and is configured to be connected to the first cabinet body and/or the second cabinet body.

In a third aspect, the present disclosure provides a cabinet group assembly, including a first cabinet body, a second cabinet body, and the cable unit provided by the present disclosure, where nodes are provided on the first cabinet body and the second cabinet body, and the connection terminals are connected to the nodes.

Other features and advantages of the present disclosure will be described in detail in the following Detailed Description section.

### BRIEF DESCRIPTION OF DRAWINGS

The above and other features, advantages, and aspects of the embodiments of the present disclosure will become more apparent in combination with the drawings and with reference to the following Detailed Description section. Throughout the drawings, the same or similar reference numerals represent the same or similar elements. It should be understood that the drawings are schematic, and the components and elements are not necessarily drawn to scale. In the drawings:

FIG. 1 is a schematic structural diagram of a cable assembly provided by an exemplary embodiment of the present disclosure.

FIG. 2 is a schematic structural diagram of a cable management rack provided by an exemplary embodiment of the present disclosure.

FIG. 3 is a schematic structural diagram of two cabinet bodies provided by an exemplary embodiment of the present disclosure.

FIG. 4 is a schematic diagram of a cabinet group assembly provided by an exemplary embodiment of the present disclosure.

FIG. 5 is an enlarged view of a portion A in FIG. 4.

FIG. 6 is a schematic diagram of a cabinet group assembly provided by another exemplary embodiment of the present disclosure.

FIG. 7 is an enlarged view of a portion B in FIG. 6.

FIG. 8 is a schematic diagram of a cabinet group assembly provided by an exemplary embodiment of the present disclosure in a working state.

FIG. 9 is a schematic diagram of a cabinet group assembly provided by an exemplary embodiment of the present disclosure in a maintenance state.

FIG. 10 is an enlarged view of a portion C in FIG. 9.

FIG. 11 is a front partial view of a cabinet group assembly provided by an exemplary embodiment of the present disclosure in a maintenance state.

FIG. 12 is a front partial view of a cabinet group assembly provided by another exemplary embodiment of the present disclosure in a maintenance state.

### DESCRIPTION OF REFERENCE NUMERALS IN THE ACCOMPANYING DRAWINGS

200—cable unit, 210—cable assembly, 211—cable, 2111—end section, 2112—extension section, 2113—bending section, 212—connection terminal, 220—cable management rack, 221—bearing body, 2211—bottom wall, 2212—side wall, 2213—hollowed-out portion, 222—mounting base, 223—hovering mechanism, 301—node, 302—switch, 310—first cabinet body, 320—second cabinet body.

### DETAILED DESCRIPTION

Hereinafter, embodiments of the present disclosure will be described in more detail with reference to the drawings. Although certain embodiments of the present disclosure are shown in the drawings, it should be understood that the present disclosure may be implemented in various forms, and should not be construed as limited to the embodiments set forth herein; on the contrary, these embodiments are provided for a more thorough and complete understanding of the present disclosure. It should be understood that the drawings and embodiments of the present disclosure are only used for illustrative purposes, and are not used to limit the protection scope of the present disclosure.

As used herein, the term “include/comprise” and its variations are open-ended inclusions, that is, “include/comprise but not limited to”. The term “based on” is “based at least in part on”. The term “an embodiment” means “at least one embodiment”. The term “another embodiment” means “at least another embodiment”. The term “some embodiments” means “at least some embodiments”. Relevant definitions of other terms will be given in the following description.

It should be noted that concepts such as “first” and “second” mentioned in the present disclosure are only used to distinguish different apparatuses, modules or units, and are not used to limit the order or interdependence of the functions performed by these apparatuses, modules or units.

It should be noted that the modifications of “a/an/one” and “a plurality of” mentioned in the present disclosure are illustrative rather than restrictive, and those skilled in the art should understand that unless otherwise explicitly indicated in the context, it should be understood as “one or more”.

With the rapid development of electronic devices and communication technologies, the arranging density of cables is increasing day by day, and the orderly arrangement of cables and later maintenance have become crucial in various cabinets. For the existing two cabinet bodies, a wiring interconnection method for high-density cables is usually to perform wiring and interconnection on a side surface of the cabinet body. For example, when a first cabinet body 310 is interconnected with a second cabinet body 320, a cable connected to the first cabinet body 310 is led out to a side away from the second cabinet body 320 and then runs upwards along a side wall of the first cabinet body 310, and then after running on top walls of the first cabinet body 310 and the second cabinet body 320, the cable runs downwards from a side of the second cabinet body 320 away from the first cabinet body 310 and then is connected to the second cabinet body 320. The total wiring length of this wiring method is very long, up to several meters, which leads to a significant increase in cost. When the cables are arranged in front of the cabinet body in order to save wiring, the interconnection relationship will be complicated and the wiring will be cumbersome. The existing arrangement scheme is in a mess, which causes great difficulties in installation or maintenance.

In order to effectively solve this problem, the present disclosure provides a solution with a more regular arrangement. Specifically, an embodiment of the present disclosure provides a cable assembly 210. As shown in FIG. 1, the cable assembly 210 includes two groups of connection terminals 212 and at least two cables 211 connected between the two groups of connection terminals 212, where one of the two groups of connection terminals 212 is configured to be connected to a first cabinet body 310, and the other of the two groups of connection terminals 212 is configured to be connected to a second cabinet body 320, so as to realize the interconnection between the two cabinet bodies. Moreover, the cables 211 connected between the two groups of connection terminals 212 are configured to span across a front side of the first cabinet body 310 and a front side of the second cabinet body 320. The terms “horizontal, front, rear” and the like involved in the present disclosure are all defined according to the use habits of the cabinet group assembly. The fact that the cables 211 span across the front side of the first cabinet body 310 and the front side of the second cabinet body 320 is intended to reflect that in the solution of the embodiment of the present disclosure, the cables 211 directly run in front of the cabinet body, instead of running from the side to the top and then back to the side as in the prior art. Compared with the “ [symbol] ”-shaped wiring in the prior art, the cables 211 in the present application are substantially “-”-shaped wiring. The connection terminals 212 may be arranged to be directly plugged and unplugged with nodes 301 of the cabinet body, so as to facilitate the installation.

Through the above technical solution, in the embodiment of the present disclosure, a plurality of cables 211 are prefabricated into one cable assembly 210, and during a wiring process, the plurality of cables 211 can be connected as one cable assembly 210, so as to avoid a large number of cables 211 from being stacked difficultly due to the independent existence of the cables 211. After the plurality of cables 211 are prefabricated into the cable assembly 210, the wiring efficiency can be improved, and with the use of the cable assembly 210, during the maintenance of a certain cable assembly 210, the cable assembly 210 can be quickly identified, and other cable assemblies 210 do not need to be disassembled, thereby reducing the difficulty in maintenance. The cables 211 are arranged to span across the front side, which can effectively reduce the wiring length, reduce the cost, and make the operation more convenient.

In the embodiment of the present disclosure, the cables 211 connected between the two groups of connection terminals 212 have the same length, so as to facilitate the manufacture of the cable assembly 210 without designing cables 211 of various lengths, which is convenient for management and saves development costs, and can also avoid the situation of misassembly when manufacturing the cable assembly 210.

A cabinet group assembly is usually provided with a large number of cables 211 in a height direction, in order to avoid excessive density caused by excessive stacking, and avoid the increasing of wiring difficulty, in the embodiment of the present disclosure, the plurality of cables 211 may be configured such that the maximum stacking height is not greater than the sum of the diameters of two cables 211, that is, each cable assembly 210 may have at most two layers of cables stacked. Certainly, it may also be understood that in other embodiments, when the number of cables 211 is small, multiple layers may also be stacked.

As shown in FIG. 1, each cable 211 may include end sections 2111 at two ends, and the end sections 2111 are connected to the connection terminals 212. The end sections 2111 of the plurality of cables 211 are arranged in a flat arrangement along a first direction, and the first direction is an arrangement direction of the first cabinet body 310 and the second cabinet body 320. The flat arrangement of the end sections 2111 can make the arrangement of the cables 211 at the ends clearer and more visible, which is convenient for manufacture and installation, and also convenient for tracking.

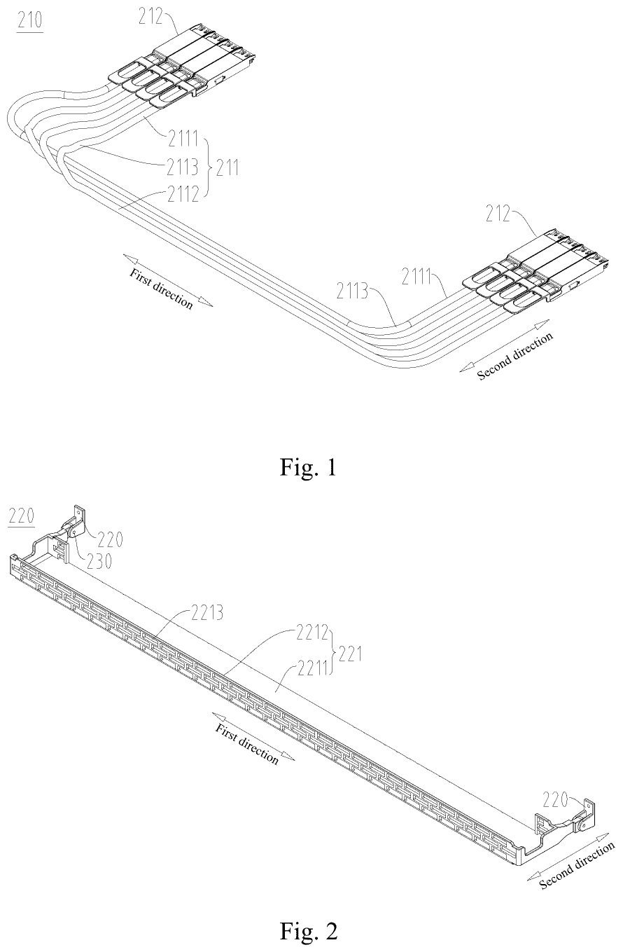

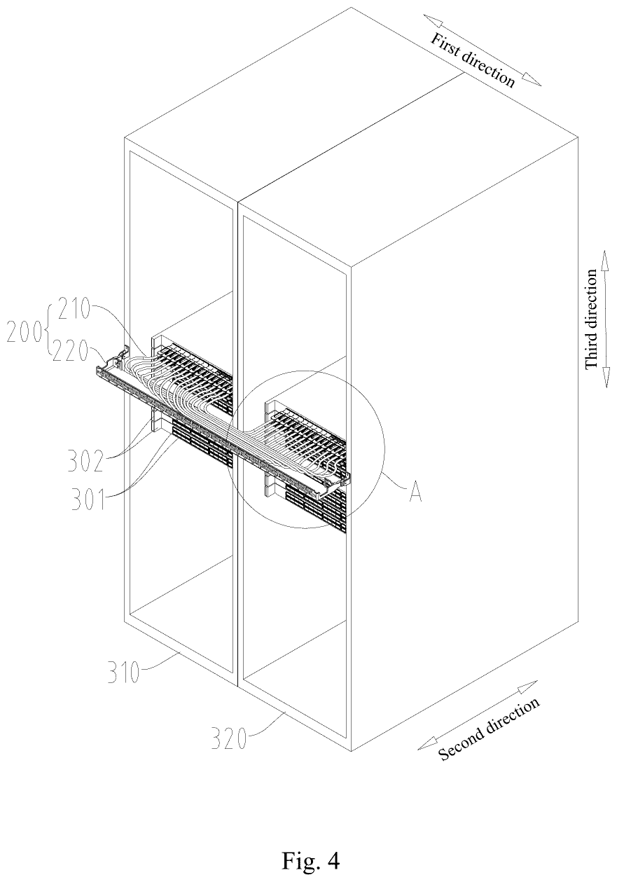

As shown in FIG. 2, each cable 211 may include an extension section 2112. In combination with FIG. 4, the extension section 2112 is configured to span across the front side of the first cabinet body 310 and the front side of the second cabinet body 320, and the extension sections 2112 of the cables 211 are arranged in a flat arrangement along a second direction, and the second direction is a front-back direction of the first cabinet body 310 and the second cabinet body 320. The extension section 2112 is arranged across the front side of the first cabinet body 310 and the front side of the second cabinet body 320, which is also a good viewing angle. Therefore, the flat arrangement of the extension sections 2112 can avoid poor vision caused by stacking in the height direction, and reduce the difficulty in installation and subsequent maintenance.

As shown in FIG. 1, in addition to the above-mentioned end sections 2111 and the above-mentioned extension section 2112, each cable 211 further includes a bending section 2113. There are two end sections 2111 and two bending sections 2113, the two end sections 2111 are respectively connected to the two groups of connection terminals 212, and each bending section 2113 is connected between the end section 2111 and the extension section 2112. The bending section 2113 may be arranged to provide a redundancy for the cable 211, so as to ensure that the cables 211 have the same length, and can also create conditions for the flat arrangement of the cables 211, so as to facilitate the adjustment of the relative positions between the plurality of cables 211.

The stacking height at the connection position between the extension section 2112 and the bending section 2113 at one end is equal to the sum of diameters of two cables 211, as shown in FIG. 1, the stacking height at the connection between the bending section 2113 on the left side in the figure and the extension section 2112 is equal to the sum of diameters of two cables 211, that is, two layers of cables 211 are stacked, while only one layer of cable 211 is provided at the connection between the bending section 2113 on the right side and the extension section 2112. With this stacking method, the cables 211 may have the same length, and the flat arrangement at other positions is facilitated.

The bending section 2113 at each end of each of the plurality of cables 211 is configured such that the bending length is gradually reduced from the outside to the inside. The outside and the inside here are defined according to the first direction, that is, the two ends along the first direction are the outside. The bending length here refers to the redundancy designed to adjust the plurality of cables 211 to be equal in length. That is, the closer the cable 211 is to the outside of the cabinet group assembly, the more the redundant length is, so as to facilitate the arrangement of the inner cables 211, and make the cable assembly 210 more regular.

In the embodiment of the present disclosure, the connection sequence of the two ends of the plurality of cables 211 with the connection terminals 212 is the same, so that the connection mode between the two cabinet bodies is “left to left, right to right”. In short, when each cable assembly 210 includes four cables 211, the four cables 211 are numbered as cable 1, cable 2, cable 3 and cable 4 respectively. At the left connection terminal 212, the four cables 211 are connected from left to right in the order of cable 1, cable 2, cable 3 and cable 4. Similarly, at the right connection terminal 212, the four cables 211 are also connected in this order, so that the connection sequence on both sides is the same, and the difficulty in cable interconnection between the two cabinet bodies is also reduced.

According to an embodiment of the present disclosure, the cable assembly 210 may include four cables 211. In other embodiments, other number of cables 211 may be provided according to the actual number of nodes 301.

In the embodiment of the present disclosure, the cables 211 may be copper cables. The copper cable is lower in price than an optical fiber, but the copper cable has a larger diameter than the optical fiber. When there are more nodes 301 on the node cabinet body, the copper cable has a larger wiring density and a larger line of sight occlusion during connection or operation and maintenance. In the embodiment of the present disclosure, the plurality of cables 211 are made into the cable assembly 210, and the cables can directly run on the front side of the cabinet body, which reduces the difficulty in interconnection and saves the cost to a great extent.

Through the above technical solutions, in the embodiments of the present disclosure, a plurality of cables are prefabricated into one cable assembly, and during a wiring process, the plurality of cables may be connected as one cable assembly, so as to avoid a large number of cables from being stacked difficultly due to the independent existence of the cables. After the plurality of cables are prefabricated into the cable assembly, the wiring efficiency can be improved, and with the use of the cable assembly, during the operation and maintenance of a certain cable assembly, the cable assembly can be quickly identified, and other cable assemblies do not need to be disassembled, thereby reducing the difficulty in operation and maintenance. The cables are arranged to span across the front side of the cabinet body, which can effectively reduce the wiring length, reduce the cost, and make the operation more convenient.

According to a second aspect of the embodiments of the present disclosure, a cable unit 200 is provided. Referring to FIG. 4, the cable unit 200 includes a cable management rack 220 and the above-mentioned cable assembly 210, and the cable management rack 220 is supported below the cable assembly 210 and is configured to be connected to the first cabinet body 310 and/or the second cabinet body 320. Two cable management racks 220 may be provided, one is connected to the first cabinet body 310 and the other is connected to the second cabinet body 320, so as to respectively support the cables 211 connected to the two cabinet bodies; or, one cable management rack 220 may be provided, one end of the cable management rack is connected to the first cabinet body 310, and the other end of the cable management rack is connected to the second cabinet body 320, so as to support the cables 211 connected between the two cabinet bodies at the same time. The cable unit 200 has all the beneficial effects of the above-mentioned cable assembly 210, which will not be repeated here.

In the embodiment of the present disclosure, the cable assembly 210 is arranged to span across the front side of the cabinet body, and the cable management rack 220 is arranged below the cable assembly 210 to clearly distinguish the cable assemblies 210 arranged above and below, so as to clearly find the expected position during installation or operation and maintenance, thereby reducing the difficulty in wiring and operation and maintenance.

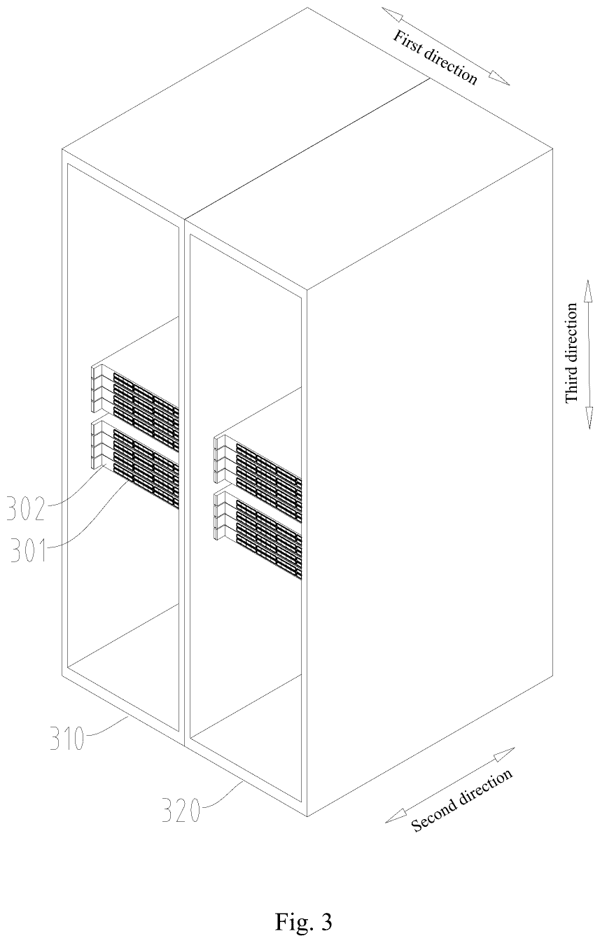

According to a third aspect of the embodiments of the present disclosure, a cabinet group assembly is provided. Referring to FIG. 3 to FIG. 12, the cabinet group assembly includes a first cabinet body 310, a second cabinet body 320, and the above-mentioned cable unit 200, where nodes 301 are provided on the first cabinet body 310 and the second cabinet body 320, and the connection terminals 212 are connected to the nodes 301. The cabinet group assembly has all the beneficial effects of the above-mentioned cable unit 200, which will not be repeated here. The first cabinet body 310 and the second cabinet body 320 may be arranged along a first direction, the front-back direction of the first cabinet body 310 and the second cabinet body 320 is a second direction, and the height direction of the first cabinet body 310 and the second cabinet body 320 is a third direction. The cabinet group assembly may be used in, but not limited to, a networking scenario of servers or network devices.

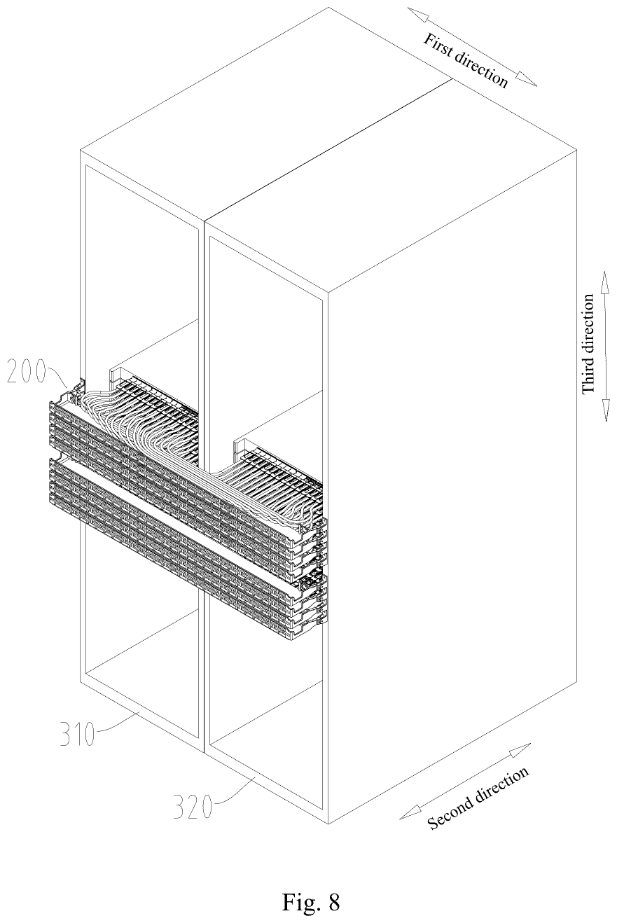

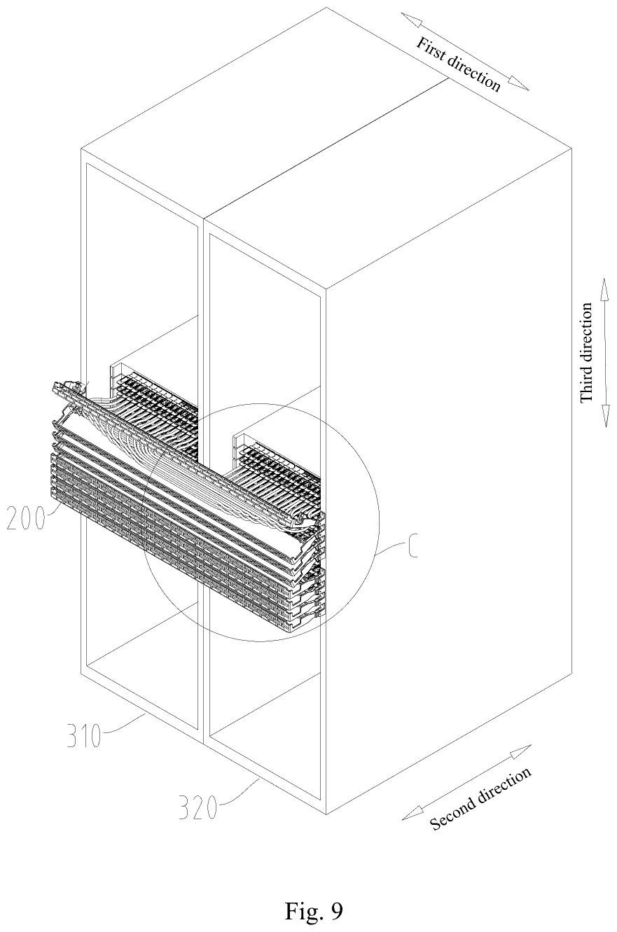

In the embodiment of the present disclosure, the cable management rack 220 of the cable unit 200 is configured to be movable, so as to switch between a working state and a maintenance state. Referring to FIG. 8, the cable management rack 220 is shown in the working state, and FIG. 9 to FIG. 12 show the cable management rack 220 in the maintenance state. The cable management rack 220 shields a maintenance space in the working state and releases the maintenance space in the maintenance state. The maintenance space here refers to the space required when the cables 211 or the nodes 301 on the cabinet body need to be operated and maintained. In the working state, the space is shielded by the cable management rack 220, and when maintenance is required, the cable management rack 220 can give way to the space, so as to facilitate the maintenance operation.

As shown in FIG. 2, the cable management rack 220 provided by the embodiment of the present disclosure includes a bearing body 221 and a mounting base 222. The bearing body 221 is configured to bear the cables 211, that is, the cables 211 can be supported by the cable management rack 220, for example, the cables 211 may be supported above the cable management rack 220. The mounting base 222 is configured to be mounted to the cabinet body, where at least the bearing body 221 is configured to be movable, for example, only the bearing body 221 may be movable, or both the bearing body 221 and the mounting base 222 may be movable, so as to achieve the above-mentioned working state and maintenance state.

In an embodiment, the bearing body 221 and the mounting base 222 are rotatably connected around the first direction, and the first direction is an arrangement direction of the first cabinet body 310 and the second cabinet body 320. The first direction is the arrangement direction of the first cabinet body 310 and the second cabinet body 320, that is, the bearing body 221 may rotate upwards and downwards relative to the mounting base 222, that is, rotate upwards and downwards relative to the cabinet body.

Through the above technical solution, with the relative rotational connection between the mounting base 222 and the bearing body 221, the cable management rack 220 for supporting the cables 211 can rotate upwards and downwards after being mounted on the cabinet body, thereby driving the cables 211 supported thereon to move. When maintenance needs to be performed on a certain place, the cable management rack 220 around a maintenance region may be rotated to vacate a larger maintenance space for the maintenance region, so as to facilitate the operation of hands or tools of the operation and maintenance personnel, and reduce the difficulty in operation and maintenance.

In the embodiment of the present disclosure, a hovering mechanism 223 may be connected between the bearing body 221 and the mounting base 222, and the hovering mechanism 223 may enable the bearing body 221 to hover when the bearing body 221 is rotated to a preset position, so as to ensure the reliability of the rotation of the bearing body 221 without random falling to affect the operation and maintenance. The hovering mechanism 223 may be implemented in a variety of ways, such as friction damping, that is, a friction plate is arranged between the mounting base 222 and the bearing body 221, and when the bearing body 221 is rotated to the preset position, the friction force can balance an external force, so that the bearing body 221 is kept in the current position, or a mechanical locking method may be used, that is, a clamping slot or a locking hole is arranged on the bearing body 221 and the mounting base 222, and when the bearing body 221 is rotated to the preset position, the locking may be realized by inserting a locking pin into the clamping slot or the locking hole, so as to fix the bearing body 221 in this position. The hovering mechanism 223 may also be realized by means of hydraulic damping, ratchet and pawl, etc., and the specific implementation of the hovering mechanism 223 is not limited in the present disclosure.

The hovering mechanism 223 may be arranged to enable the bearing body 221 to hover at any rotation position of the bearing body 221, or may be arranged to enable the bearing body 221 to hover at least at a first rotation position and a second rotation position, the first rotation position is configured as the working state, that is, the cable management rack 220 is in a state of normally supporting the cables 211 as shown in FIG. 8, and the second rotation position is configured as the maintenance state, that is, the cable management rack 220 is in a state of being rotated by a certain angle as shown in FIG. 9 to FIG. 12, so that the bearing body 221 has at least two positions. In other embodiments, the bearing body 221 may have three positions, including one position in the working state and two positions in different maintenance states, or as mentioned above, the bearing body 221 may have any hovering position, and may be hovered to different regions according to actual needs.

According to an embodiment of the present disclosure, the maximum rotation angle of the bearing body 221 in the second rotation position compared with the bearing body 221 in the first rotation position may ranges from 20° to 30°. In other words, when the cable management rack 220 changes from the working state to the maintenance state, the maximum angle by which the cable management rack 220 may rotate upwards or downwards ranges from 20° to 30°, for example, 20°, 250 or 30°. When the rotation range of the cable management rack 220 is too small, enough operation and maintenance space cannot be provided, and the operation and maintenance difficulty is relatively large; when the rotation range of the cable management rack 220 is too large, the cables 211 may be driven to rotate by too large an angle, which may cause damage to the cables 211. In the embodiment of the present disclosure, the maximum angle of the bearing body 221 is limited to 20° to 30°, which can ensure enough operation and maintenance space and avoid damaging the cables 211.

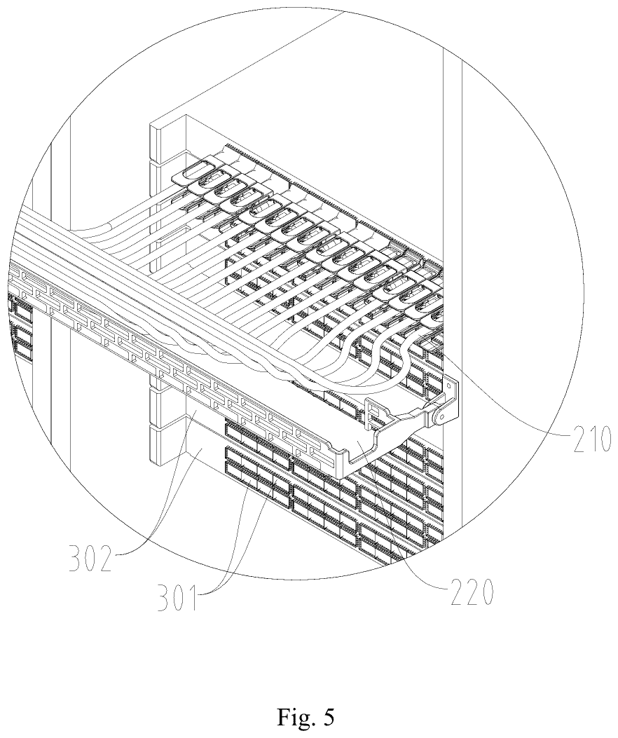

Referring to FIG. 4 and FIG. 5, the cross section of the bearing body 221 may be configured to be L-shaped, so that the bearing body 221 has a bottom wall 2211 and a side wall 2212, as shown in FIG. 2. The bottom wall 2211 may be supported at the bottom of the cables 211, and the side wall 2212 may stop/limit at the front side of the cables 211. As shown in FIG. 5, the cables 211 extend from the outside of the bearing body 221 to the bearing body 221 and are borne on the bottom wall 2211, and the side wall 2212 may stop/limit the cables 211, so as to prevent the cables 211 from interfering with other structures, and also make the arrangement of the cables 211 neater, and facilitate the quick positioning to the maintenance region during maintenance.

As shown in FIG. 2, a plurality of hollowed-out portions 2213 may be formed on the bearing body 221, and the design of the hollowed-out portions 2213 reduces the weight of the cable management rack 220, and is also beneficial to the heat dissipation of the cables 211.

According to another embodiment of the present disclosure, in addition to the above-mentioned rotatable bearing body 221, the movable mode of the cable management rack 220 may also be: the bearing body 221 being detachably arranged on the mounting base 222, or the mounting base 222 being detachably arranged on the first cabinet body 310 or the second cabinet body 320. In the maintenance state, the bearing body 221 may be removed from the mounting base 222, or the mounting base 222 may be removed from the cabinet body.

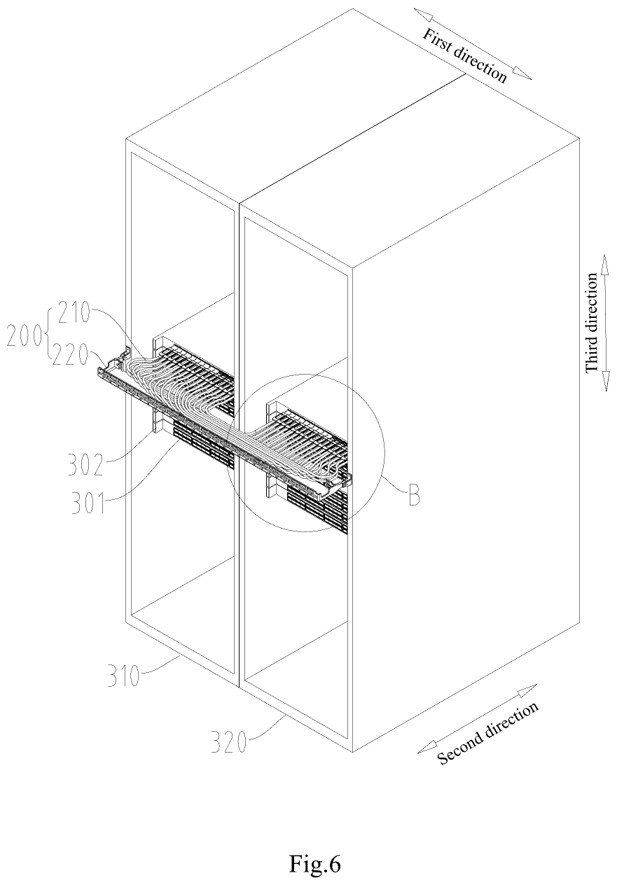

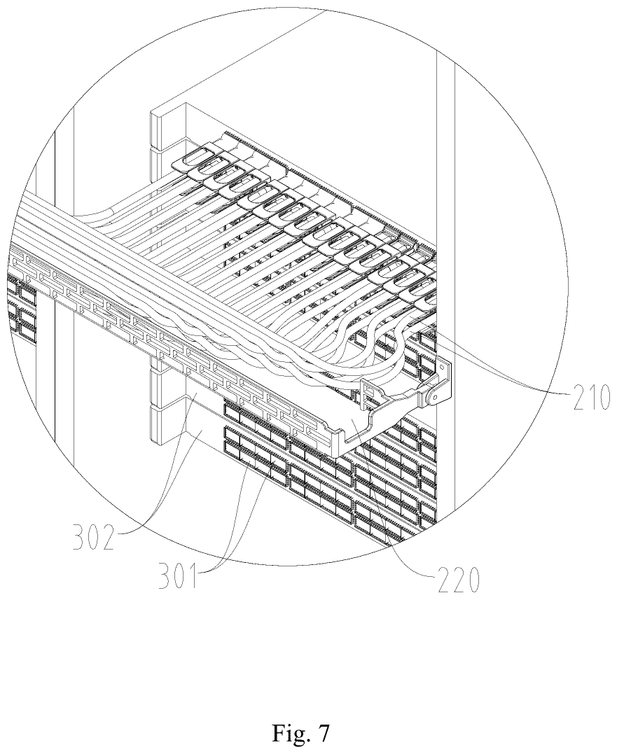

In the embodiment of the present disclosure, referring to FIG. 4 and FIG. 5, the cable unit 200 includes a plurality of groups of cable assemblies 210, and the plurality of groups of cable assemblies 210 are arranged along a first direction and/or a third direction, the first direction is an arrangement direction of the first cabinet body 310 and the second cabinet body 320, and the third direction is a height direction of the first cabinet body 310 and the second cabinet body 320. In the embodiments shown in FIG. 4 and FIG. 5, the plurality of groups of cable assemblies 210 are arranged along the first direction, and in the embodiments shown in FIG. 6 and FIG. 7, the plurality of groups of cable assemblies 210 are arranged along the first direction and the third direction. Taking a cable unit 200 applied to thirty-two nodes 301 and the cable assembly 210 including four cables 211 as an example, four cable assemblies 210 may be arranged along the first direction, and the four cable assemblies 210 correspond to sixteen nodes. The four cable assemblies 210 may be replicated to arrange in a row along the third direction, as shown in FIG. 7, two layers of cable assemblies 210 are arranged, and the two layers of cable assemblies 210 correspond to thirty-two nodes. In other embodiments, the number and arrangement of the cable assemblies 210 may be adjusted adaptively according to the actual number, positions, etc., of the nodes 301.

Referring to FIG. 8 to FIG. 12, the cabinet group assembly may include a plurality of cable units 200, and the plurality of cable units 200 may be arranged along the third direction. The cable assemblies 210 of the plurality of cable units 200 may be separated by the cable management rack 220 of the cable unit 200, so that the wiring of the cabinet group assembly is regular.

Referring to FIG. 6 and FIG. 7, the first cabinet body 310 and the second cabinet body 320 each include a plurality of switches 302 arranged along the third direction, and the nodes 301 are formed on the switches 302, that is, a plurality of nodes 301 may be formed on each switch 302, and each switch 302 is correspondingly provided with one cable unit 200, which is more convenient to distinguish the cables 211 of different switches 302.

In the embodiment of the present disclosure, a nodes 301 are formed on each switch 302, the a nodes 301 are arranged in b layers along the third direction, each cable assembly 210 includes c cables 211, the plurality of cable assemblies 210 in each cable unit 200 are arranged in b layers, and d cable assemblies 210 are arranged in each layer, where a, b, c and d are all integers, and d=a/(b×c). For example, in an embodiment, a may be thirty-two, and b may be two, that is, sixteen nodes 301 may be arranged on each layer of each switch 302, and each cable unit 200 may be arranged with two layers of cable assemblies 210, c may be four, and in this application scenario, d is four, that is, four cable assemblies 210 are arranged on each layer. In other embodiments, a, b, c and d may take other values that meet the formula.

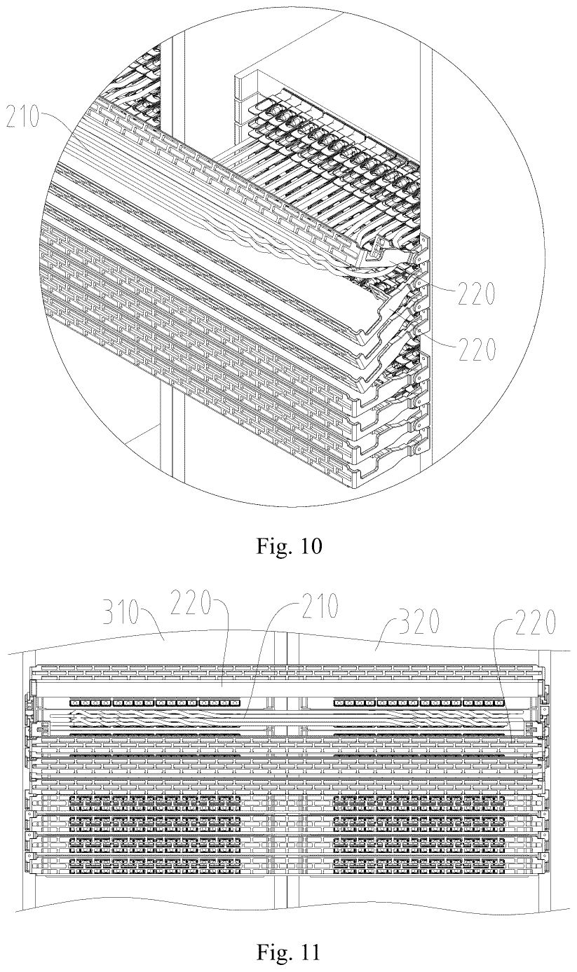

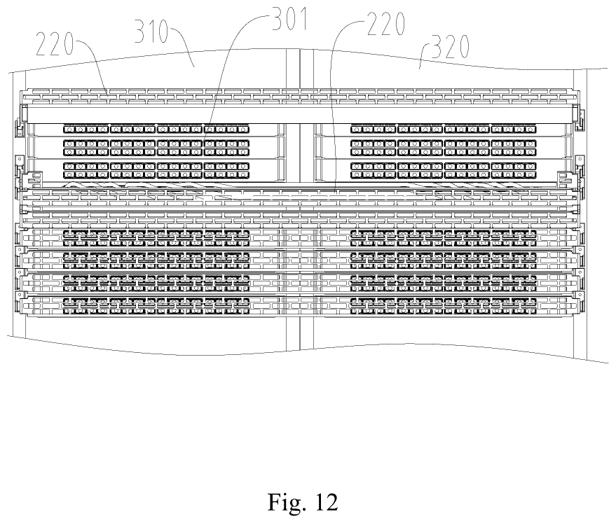

In the embodiment of the present disclosure, when a certain layer needs to be operated and maintained, enough maintenance space may be obtained by rotating the upper and lower cable management racks 220 of this layer away, as shown in FIG. 9 and FIG. 10. When a small maintenance space is required, for example, when the cables 211 need to be operated and maintained, the cable management racks 220 of the upper and lower layers of the layer to be maintained may be rotated away, as shown in FIG. 11; when a large maintenance space is required, for example, when the nodes 301 need to be operated and maintained, more layers of cable management racks 220 above and below the layer to be maintained may be rotated away, as shown in FIG. 12. FIG. 11 shows that the cable management rack 220 rotates to give way to a small maintenance space, and FIG. 12 shows that the cable management rack 220 rotates to give way to a large maintenance space. Compared with the existing wiring mode, the wiring mode in the embodiment of the present disclosure is more regular, and is simpler and easier to operate in terms of both connection, and maintenance.

The above description is only preferred embodiments of the present disclosure and an illustration of the technical principles employed. Those skilled in the art should understand that the scope of disclosure involved in the present disclosure is not limited to the technical solutions formed by the specific combination of the above technical features, and should also cover other technical solutions formed by arbitrary combination of the above technical features or their equivalent features without departing from the above disclosed concept, for example, (but not limited to) a technical solution formed by replacing the above features with the technical features with similar functions disclosed in the present disclosure.

Additionally, although operations are depicted in a particular order, it should not be understood that these operations are required to be performed in a specific order as shown or in a sequential order. Under certain circumstances, multitasking and parallel processing may be advantageous. Likewise, although the above discussion includes several specific implementation details, these should not be interpreted as limitations on the scope of the present disclosure. Certain features that are described in the context of separate embodiments may also be implemented in combination in a single embodiment. Conversely, various features that are described in the context of a single embodiment may also be implemented in multiple embodiments separately or in any suitable sub-combination.

Although the subject matter has been described in language specific to structural features and/or method logical actions, it should be understood that the subject matter defined in the appended claims is not necessarily limited to the specific features or actions described above. Rather, the specific features and actions described above are merely example forms of implementing the claims. With regard to the apparatuses in the above embodiments, the specific manner in which each module performs an operation has been described in detail in the embodiments relating to the method, and will not be detailed herein.

1. A cable assembly, comprising two groups of connection terminals (212) and at least two cables (211) connected between the two groups of connection terminals (212), wherein one of the two groups of connection terminals (212) is configured to be connected to a first cabinet body (310), the other of the two groups of connection terminals (212) is configured to be connected to a second cabinet body (320), and the cables (211) connected between the two groups of connection terminals (212) are configured to span across a front side of the first cabinet body (310) and a front side of the second cabinet body (320).

2. The cable assembly according to claim 1, wherein the cables (211) connected between the two groups of connection terminals (212) have a same length.

3. The cable assembly according to claim 1, wherein the cables (211) are configured such that a maximum stacking height is not greater than a sum of diameters of two cables (211).

4. The cable assembly according to claim 1, wherein each of the cables (211) comprises end sections (2111) at two ends, the end sections (2111) are respectively connected to the two groups of connection terminals (212), and end sections (2111) of the cables (211) are arranged in a flat arrangement along a first direction, the first direction is an arrangement direction of the first cabinet body (310) and the second cabinet body (320); and/or
each of the cables (211) comprises an extension section (2112), the extension section (2112) is configured to span across the front side of the first cabinet body (310) and the front side of the second cabinet body (320), and extension sections (2112) of the cables (211) are arranged in a flat arrangement along a second direction, the second direction is a front-back direction of the first cabinet body (310) and the second cabinet body (320).

5. The cable assembly according to claim 1, wherein each of the cables (211) comprises an end section (2111), an extension section (2112) and a bending section (2113), the end section (2111) is connected to the connection terminal (212), the extension section (2112) is configured to span across the front side of the first cabinet body (310) and the front side of the second cabinet body (320), and the bending section (2113) is connected between the end section (2111) and the extension section (2112).

6. The cable assembly according to claim 5, wherein a stacking height at a connection position between the extension section (2112) and the bending section (2113) at one end is equal to a sum of diameters of two cables (211).

7. The cable assembly according to claim 5, wherein a bending section (2113) at each end of the cables (211) is configured such that a bending length is gradually reduced from an outside to an inside; and/or two ends of the cables (211) are connected to the connection terminals (212) in a same order.

8. The cable assembly according to claim 1, wherein the cables (211) are copper cables.

9. A cable unit, comprising a cable management rack (220) and the cable assembly (210) according to claim 1, wherein the cable management rack (220) is supported below the cable assembly (210) and is configured to be connected to the first cabinet body (310) and/or the second cabinet body (320).

10. The cable unit according to claim 9, wherein the cable management rack (220) is configured to be movable to switch between a working state and a maintenance state, and the cable management rack (220) shields maintenance space in the working state and releases the maintenance space in the maintenance state.

11. The cable unit according to claim 10, wherein the cable management rack (220) comprises:
a bearing body (221) configured to bear the cables (211); and
a mounting base (222) configured to be mounted to the first cabinet body (310) and/or the second cabinet body (320),
wherein at least the bearing body (221) is configured to be movable.

12. The cable unit according to claim 11, wherein the bearing body (221) and the mounting base (222) are rotatably connected around a first direction, and wherein the first direction is an arrangement direction of the first cabinet body (310) and the second cabinet body (320).

13. The cable unit according to claim 12, wherein a hovering mechanism (223) is connected between the bearing body (221) and the mounting base (222), the hovering mechanism (223) is configured to enable the bearing body (221) to hover at least at a first rotation position and a second rotation position, the first rotation position is configured as the working state, and the second rotation position is configured as the maintenance state.

14. The cable unit according to claim 13, wherein the bearing body (221) is configured such that a maximum rotation angle of the bearing body (221) in the second rotation position compared with the bearing body (221) in the first rotation position ranges from 20° to 30°.

15. The cable unit according to claim 11, wherein the bearing body (221) is detachably arranged on the mounting base (222), or the mounting base (222) is detachably arranged on the first cabinet body (310) or the second cabinet body (320).

16. The cable unit according to claim 9, wherein the cable unit (200) comprises a plurality of groups of cable assemblies (210), and the plurality of groups of cable assemblies (210) are arranged along a first direction and/or a third direction, the first direction is an arrangement direction of the first cabinet body (310) and the second cabinet body (320), and the third direction is a height direction of the first cabinet body (310) and the second cabinet body (320).

17. A cabinet group assembly, comprising a first cabinet body (310), a second cabinet body (320) and the cable unit (200) according to claim 9, wherein nodes (301) are provided on the first cabinet body (310) and the second cabinet body (320), and the connection terminals (212) are connected to the nodes (301).

18. The cabinet group assembly according to claim 17, wherein the cabinet group assembly comprises a plurality of cable units (200), the plurality of cable units (200) are arranged along a third direction, and the third direction is a height direction of the first cabinet body (310) and the second cabinet body (320).

19. The cabinet group assembly according to claim 18, wherein the first cabinet body (310) and the second cabinet body (320) each comprise a plurality of switches (302) arranged along the third direction, the nodes (301) are formed on the switches (302), and each of the switches (302) is correspondingly provided with one cable unit (200).

20. The cabinet group assembly according to claim 19, wherein a nodes (301) are formed on each of the switches (302), the a nodes (301) are arranged in b layers along the third direction, each cable assembly (210) comprises c cables (211), the plurality of cable assemblies (210) in each cable unit (200) are arranged in b layers, and d cable assemblies (210) are arranged in each of the layers, wherein a, b, c and d are all integers, and
$$d = \frac{a}{( b \times c )} .$$
